(19) United States
(12) Patent Application Publication
(10) Pub. No.: US 2024/0072200 A1
(43) Pub. Date: Feb. 29, 2024

(54) METHOD OF MANUFACTURING LIGHT-EMITTING DEVICE, METHOD OF MANUFACTURING LIGHT-EMITTING MODULE, LIGHT-EMITTING DEVICE, AND LIGHT-EMITTING MODULE

(71) Applicant: NICHIA CORPORATION, Anan-shi (JP)

(72) Inventors: Tetsuya ISHIKAWA, Komatsushima-shi (JP); Gensui TAMURA, Anan-shi (JP)

(73) Assignee: NICHIA CORPORATION, Anan-shi (JP)

(21) Appl. No.: 18/451,928

(22) Filed: Aug. 18, 2023

(30) Foreign Application Priority Data
Aug. 31, 2022 (JP) 2022-137925

(51) Int. Cl. H01L 33/00; H01L 27/15; H01L 33/56; H01L 33/60; H01L 33/62

(52) U.S. Cl. CPC H01L 33/0095; H01L 27/156; H01L 33/56; H01L 33/60; H01L 33/62

(57) ABSTRACT

A method of manufacturing a light-emitting device includes: preparing a light source, which includes: (a) preparing a structure including: a support substrate having a first upper face and including, on the first upper face, a plurality of first terminal parts disposed in the light-emitting part arrangement region, and one or more first wire-connection parts, and a plurality of light-emitting parts disposed in the light-emitting part arrangement region and electrically connected to the first terminal parts, each of the plurality of light-emitting parts having an emission face, (b) disposing a resin member on the first upper face between the light-emitting part arrangement region and the one or more first wire-connection parts in a top view, and (c) disposing a light-shielding member in contact with the resin member while the first wire-connection parts and the emission faces of the light-emitting parts are exposed from the light-shielding member in the top view.

### CROSS-REFERENCE TO RELATED APPLICATIONS

The present application claims priority under 35 U.S.C. § 119 to Japanese Patent Application No. 2022-137925, filed Aug. 31, 2022, the contents of which are hereby incorporated by reference in their entirety.

### BACKGROUND

### 1. Technical Field

The present disclosure relates to a method of manufacturing a light-emitting device, a method of manufacturing a light-emitting module, a light-emitting device, and a light-emitting module.

### 2. Description of Related Art

In recent years, light sources employing light-emitting elements such as light-emitting diodes have been utilized in a broad range of applications. For example, Japanese Patent Publication Nos. 2021-044348, 2021-132145, 2020-053643, and 2018-195758, and PCT Publication No. WO 2019/064980 each disclose a light source in which a light-emitting element is encapsulated by a sealing member disposed inward of the walls provided to surround the light-emitting element.

### SUMMARY

In disposing any of the light sources disclosed in the above patent publications on a mounting member such as a mounting substrate, it is conceivable as one example to electrically connect the light source and the mounting member with a wire by using a wire bonding technique followed by covering the wire with a resin material or the like, for example.

One object of the present disclosure is to provide a method of manufacturing a light-emitting device and a method of manufacturing a light-emitting module that can simplify the electrical connection between a light source and a mounting member, as well as providing such light-emitting device and light-emitting module.

A method of manufacturing a light-emitting device according to one embodiment of the present disclosure includes:
preparing a light source including:
(a) preparing a structure, the structure including
   a support substrate having a first upper face, and the support substrate comprising, on the first upper face, a plurality of first terminal parts disposed in the light-emitting part arrangement region, and one or more first wire-connection parts, and
   a plurality of light-emitting parts disposed in the light-emitting part arrangement region and electrically connected to the first terminal parts, and each of the plurality of light-emitting parts having an emission face,
(b) disposing a resin member on the first upper face between the light-emitting part arrangement region and the first wire-connection parts in a top view, and
(c) disposing a light-shielding member disposed in contact with the resin member while exposing the first wire-connection parts and the emission faces of the light-emitting parts from the light-shielding member in the top view;

preparing a control unit having a second upper face, and the control unit having, on the second upper face, a first region where the light source can be disposed, and one or more second wire-connection parts disposed in a second region other than the first region;

disposing the light source in the first region of the control unit; and

connecting the first wire-connection parts and the second wire-connection parts by using a first wire.

A light-emitting device according to one embodiment of the present disclosure includes:

a light source, the light source including:
a support substrate having a first upper face, and the support substrate comprising, on the first upper face, a plurality of first terminal parts disposed in the light-emitting part arrangement region, and one or more first wire-connection parts,
a plurality of light-emitting parts disposed in the light-emitting part arrangement region and electrically connected to the first terminal parts, and each of the plurality of light-emitting parts having an emission face,
a resin member disposed on the first upper face between the light-emitting part arrangement region and the first wire-connection parts in a top view, and
a light-shielding member disposed in contact with the resin member while exposing the first wire-connection parts and the emission faces of the light-emitting parts from the light-shielding member in the top view;

a control unit having a second upper face, and the control unit having, on the second upper face, a first region where the light source can be disposed and one or more second wire-connection parts disposed in a second region other than the first region;

a first wire connecting the first wire-connection parts and the second wire-connection parts; and

a first cover member covering the first wire while exposing the emission faces of the light-emitting parts.

According to the present disclosure, a method of manufacturing a light-emitting device and a method of manufacturing a light-emitting module that can facilitate the electrical connection between a light source and a mounting member, as well as such light-emitting device and light-emitting module, can be provided.

### BRIEF DESCRIPTION OF THE DRAWINGS

A more complete appreciation of embodiments of the invention and many of the attendant advantages thereof will be readily obtained by reference to the following detailed description when considered in connection with the accompanying drawings.

FIG. 1A is a schematic plan view of a light-emitting device according to an embodiment of the present disclosure.

FIG. 1B is a schematic plan view of the light-emitting device in FIG. 1A in the state in which the first cover member and the second cover member are omitted.

FIG. 1C is a schematic cross-sectional view taken along line IC-IC in FIG. 1A.

FIG. 2 is a schematic plan view explaining a variation of the resin member of the light-emitting device according to the embodiment of the present disclosure.

FIG. 3 is a schematic cross-sectional view explaining a variation of the light-shielding member of the light-emitting device according to the embodiment of the present disclosure.

FIG. 4A is a schematic plan view of a light-emitting module according to an embodiment of the present disclosure.

FIG. 4B is a schematic plan view of the light-emitting module in FIG. 4A in the state in which the first to third cover members are omitted.

FIG. 4C is a schematic cross-sectional view taken along line IVC-IVC in FIG. 4A.

FIG. 5 is a schematic cross-sectional view of a light-emitting module according to another embodiment of the present disclosure.

FIG. 6 is a schematic cross-sectional view explaining a method of manufacturing a light-emitting device according to the present disclosure.

FIG. 7A is a schematic cross-sectional view explaining the method of manufacturing a light-emitting device according to the present disclosure.

FIG. 7B is a schematic plan view explaining the method of manufacturing a light-emitting device according to the present disclosure.

FIG. 8A is a schematic cross-sectional view explaining the method of manufacturing a light-emitting device according to the present disclosure.

FIG. 8B is a schematic plan view explaining the method of manufacturing a light-emitting device according to the present disclosure.

FIG. 9A is a schematic cross-sectional view explaining the method of manufacturing a light-emitting device according to the present disclosure.

FIG. 9B is a schematic plan view explaining the method of manufacturing a light-emitting device according to the present disclosure.

FIG. 10 is a schematic cross-sectional view explaining the method of manufacturing a light-emitting device according to the present disclosure.

FIG. 11A is a schematic cross-sectional view explaining the method of manufacturing a light-emitting device according to the present disclosure.

FIG. 11B is a schematic plan view explaining the method of manufacturing a light-emitting device according to the present disclosure.

FIG. 12 is a schematic plan view explaining the method of manufacturing a light-emitting device according to the present disclosure.

FIG. 13 is a schematic cross-sectional view explaining the method of manufacturing a light-emitting device according to the present disclosure.

FIG. 14 is a schematic cross-sectional view explaining the method of manufacturing a light-emitting device according to the present disclosure.

FIG. 15 is a schematic cross-sectional view explaining the method of manufacturing a light-emitting device according to the present disclosure.

FIG. 16 is a schematic cross-sectional view explaining a method of manufacturing a light-emitting module according to the present disclosure.

FIG. 17 is a schematic cross-sectional view explaining the method of manufacturing a light-emitting module according to the present disclosure.

### DETAILED DESCRIPTION

Certain embodiments of the present disclosure will be explained below with reference to the accompanying drawings. The methods of manufacturing light-emitting devices and light-emitting modules, the light-emitting devices, and the light-emitting modules described below are provided to give shape to the technical ideas of the present disclosure, and do not limit the invention unless otherwise specifically stated.

In the drawings, the same reference numerals denote members having the same functions. To make the features easily understood, the descriptions of the features are distributed among the embodiments, but the constituent elements described in different embodiments can be replaced or combined in part. The explanation of common features already described in embodiments appearing earlier might be omitted in the subsequent embodiments where the explanation is focused only on the differences. Similar effects attributable to similar features, in particular, will not be mentioned each time an embodiment is discussed. The sizes of and positional relationships between the members shown in each drawing might be exaggerated for clarity of explanation. Furthermore, as a cross-sectional view, an end face view showing a cut cross section might be used.

In the explanation below, terms indicating directions or positions (for example, “on,” “upper,” or “under,” “lower” or other terms related thereto) may occasionally be used. These terms, however, are merely used to clarify the relative directions or positions in a referenced drawing. Assuming that there are two members, for example, the positional relationship expressed by the term “on” (or “under”) in the present specification includes the case in which two members are in contact with one another and the case in which one is positioned above (or below) the other without contacting the other.

Light-Emitting Device

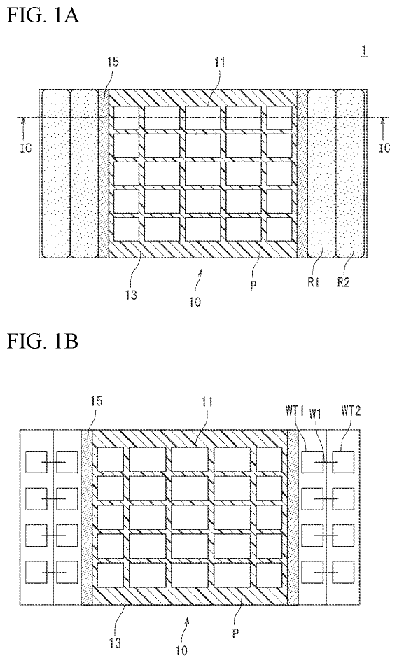

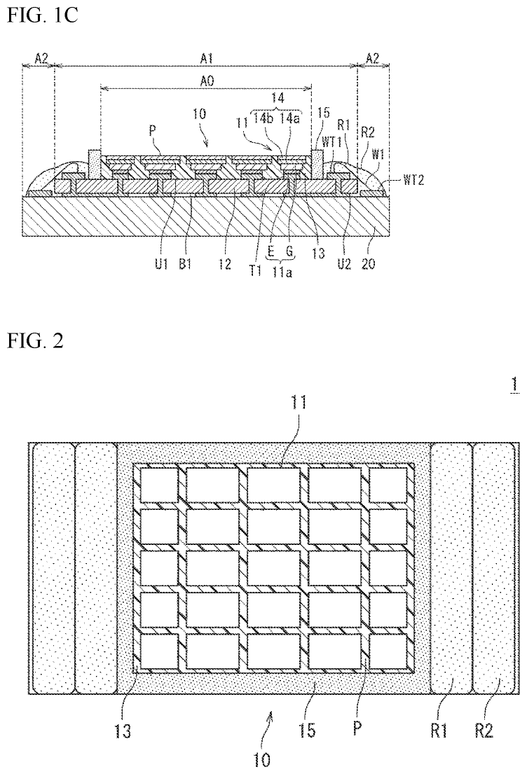

A light-emitting device 1 according to one embodiment of the present disclosure, as shown in FIG. 1A to FIG. 1C, includes a light source 10, a control unit 20, a first wire W1 that electrically connects the light source 10 and the control unit 20, and a first cover member R1 that covers a first wire-connection part WT1 provided on the light source 10. The light-emitting device 1 may further include a second cover member R2 that covers a second wire-connection part WT2 provided on the control unit 20. Each constituent of the light-emitting device 1 will be described in detail below.

Light Source

A light source 10 includes a plurality of light-emitting parts 11, a support substrate 12 having a light-emitting part arrangement region A0 for disposing the light-emitting parts 11, a light-shielding member 13 covering the light-emitting parts 11 while exposing at least the emission faces of the light-emitting parts 11, and a resin member 15 disposed between the light-emitting part arrangement region A0 and the first wire-connection parts WT1. The light source 10 illustrated in FIG. 1A has an upper face that is the emission face P that includes the emission faces of the light-emitting parts 11, and a lower face that is located opposite the upper face to serve as a mounting face.

Light-Emitting Part

The plurality of light-emitting parts 11 are arranged on the light-emitting part arrangement region A0 of the support substrate 12. In this embodiment, the light-emitting part arrangement region A0 is located generally in the center of the support substrate 12. The light-emitting parts 11 can be lit individually or in a group by the control unit 20 described below. As shown in FIG. 1A, the light-emitting parts 11 are preferably arranged in an orderly manner at equal intervals in a first direction and a second direction intersecting the first direction in a top view. In the example shown in FIG. 1A, the light-emitting parts 11 are arranged in five rows and five columns.

The light-emitting parts 11 may be lit individually or per group. Lighting the light-emitting parts 11 individually or per group allows each light-emitting part 11 to light at desired brightness, thereby improving the contrast of the irradiation region of the light source 10.

A light-emitting device 1 according to this embodiment can be used, for example, as a light source of a flashlight installed in an image pick-up device. An image pick-up device is installed in a mobile communication device, for example. In the case of using a light-emitting device 1 according to this embodiment as a light source of a flashlight in an image pick-up device, for example, the irradiation of light can be switched between a wide-angle mode where all light-emitting parts 11 are lit and a narrow-angle mode where only the light-emitting parts 11 located in the central portion are lit. The narrow-angle mode has a narrower light radiation angle than the wide-angle mode. The light-emitting device 1 capable of switching the light emission between the wide-angle mode and the narrow-angle mode allows an image pick-up device to capture an image in accordance with the type of shooting, such as a close-up or telescopic shot.

In the top view, the distance between the emission faces of two adjacent light-emitting parts 11 is preferably small. The distance between the emission faces of two adjacent light-emitting parts 11 is, for example, 0.01 to 0.16 times, preferably 0.02 to 0.08 times the maximum length of the emission face of a light-emitting part 11. The distance between the emission faces of two adjacent light-emitting parts 11 is, for example, 10 μm to 200 μm, preferably 20 μm to 100 μm. Setting the distance between the emission faces of two adjacent light-emitting parts 11 as described above can reduce the dark regions formed between the light-emitting parts 11.

The light-emitting parts 11 each have a light-emitting element 11a. The light-emitting parts 11 may each further have a light transmissive member 14 disposed on the light-emitting element 11a. The light transmissive member 14 is, for example, a sheet member substantially quadrangular in shape in the top view that is disposed to cover the upper face of a light-emitting element 11a. The light transmissive member 14 includes, for example, at least one selected from the group consisting of a wavelength conversion layer containing a wavelength conversion substance, a light diffusing layer containing a light diffusion material, and a transparent layer containing neither a wavelength conversion substance nor light diffusing material. The light transmissive member 14 includes, for example, a wavelength conversion layer 14a and a light diffusing layer 14b.

The light-emitting elements 11a each have a semiconductor structure G and electrodes E. The electrodes E include at least two, one functioning as an anode cathode and the other functioning as a cathode electrode. The light-emitting elements 11a shown in FIG. 1C have the electrodes E under the semiconductor structures G. The semiconductor structures G may each include a support substrate and a semiconductor layer disposed on the support substrate. In this case, the support substrate, the semiconductor layer, and the electrodes E are successively disposed in that order.

A semiconductor structure G includes an n-side semiconductor layer, a p-side semiconductor layer, and an active layer interposed between the n-side semiconductor layer and the p-side semiconductor layer. The active layer may have a single quantum well structure (SQW) or a structure having multiple well layers such as a multiquantum well structure (MQW). The semiconductor structure G includes a plurality of semiconductor layers made of nitride semiconductors. Nitride semiconductors can include all semiconductors obtained by varying the composition ratio x and y within their ranges in the chemical formula InₓAl_{y}Ga_{1-x-y}N (0≤x≤1, 0≤y≤1, x+y≤1). The peak emission wavelength of the light from the active layer can be suitably selected in accordance with the purpose. The active layer is constructed to emit visible light or ultraviolet light, for example.

A semiconductor structure G may include multiple emission parts each including an n-side semiconductor layer, an active layer, and a p-side semiconductor layer. In the case of including multiple emission parts in a semiconductor structure G, each emission part may include well layers emitting light of different peak emission wavelengths or the same peak emission wavelength. The same peak emission wavelength may include a variation of about several nanometers. A combination of peak emission wavelengths of the light from such emission parts can be suitably selected. For example, in the case where the semiconductor structure G includes two emission parts, combinations of light emitted by the emission parts include blue light and blue light, green light and green light, red light and red light, ultraviolet light and ultraviolet light, blue light and green light, blue light and red light, green light and red light, or the like. In the case where the semiconductor structure G includes three emission parts, for example, a combination of light emitted by the emission parts may be blue light, green light, and red light. Each emission part may include one or more well layers emitting light of a different peak emission wavelength from that of the light from the other well layers.

The wavelength conversion layer 14a converts the wavelength of at least a portion of the light from a light-emitting element 11a. The wavelength conversion layer 14a is a sheet member substantially quadrangular in shape in the top view. For the wavelength conversion material to be contained in the wavelength conversion layer 14a, for example, yttrium aluminum garnet based phosphors (e.g., (Y,Gd)₃(Al,Ga)₅O₁₂:Ce), lutetium aluminum garnet based phosphors (e.g., Lu₃(Al,Ga)₅O₁₂:Ce), terbium aluminum garnet based phosphors (e.g., Tb₃(Al,Ga)₅O₁₂:Ce), CCA-based phosphors (e.g., Ca₁₀(PO₄)₆Cl₂:Eu), SAE-based phosphors (e.g., Sr₄Al₁₄O₂₅:Eu), chlorosilicate based phosphors (e.g., Ca₈MgSi₄O₁₆Cl₂:Eu), silicate based phosphors (e.g., (Ba,Sr,Ca,Mg)₂SiO₄:Eu), oxynitride based phosphors, such as β-SiAlON based phosphors (e.g., (Si,Al)₃(O,N)₄:Eu) or α-SiAlON based phosphors (e.g., Ca(Si,Al)₁₂(O,N)₁₆:Eu), LSN-based phosphors (e.g., (La,Y)₃Si₆N₁₁:Ce), BSESN-based phosphors (e.g., (Ba,Sr)₂Si₅N₈:Eu, SLA based phosphors (e.g., SrLiAl₃N₄:Eu), nitride based phosphors, such as CASN-based phosphors (e.g., CaAlSiN₃:Eu) or SCASN-based phosphors (e.g., (Sr,Ca)AlSiN₃:Eu), fluoride based phosphors, such as KSF-based phosphors (e.g., K₂SiF₆:Mn), KSAF-based phosphors (e.g., K₂(Si₁₋ₓAlₓ)F₆₋ₓ:Mn where x satisfies 0<x<1), or MGF-based phosphors (e.g., 3.5MgO·0.5MgF₂·GeO₂:Mn), quantum dots having a Perovskite structure (e.g., (Cs,FA,MA)(Pb,Sn)(F,Cl,Br,I)₃ where FA and MA represents formamidinium and methylammonium, respectively), group II-VI quantum dots (e.g., CdSe), group III-V quantum dots (e.g., InP), or quantum dots having a chalcopyrite structure (e.g., (AgCu)(In,Ga)(S,Se)₂) can be used.

Examples of a wavelength conversion layer 14a includes a resin, ceramic, or glass containing a wavelength conversion material, a sintered body of a wavelength conversion material, and the like. The wavelength conversion layer 14a may be one in which a layer containing a wavelength conversion material is applied on one of the surfaces of a formed body made of a resin, glass, ceramic, or the like.

In the case of allowing the light-emitting parts 11 to emit white light, for example, blue light-emitting elements 11a can be combined with a wavelength conversion layer 14a containing a wavelength conversion material that emits yellow light when exposed to the light from the light-emitting elements 11a.

A light diffusing layer 14b diffuses the light entering the light diffusing layer 14b. The light diffusing layer 14b is a sheet member substantially quadrangular in shape in the top view. The light diffusing layer 14b is disposed to cover the upper face of a wavelength conversion layer 14a. For the light diffusing layer 14b, for example, a resin material containing a light diffusing material, such as titanium oxide, barium titanate, aluminum oxide, silicon oxide, or the like can be used. The planar shape of the light diffusing layer 14b in this embodiment is the same as the planar shape of the wavelength conversion layer 14a. The planar shape of the light diffusing layer 14b may be larger or smaller in size than the planar shape of the wavelength conversion layer 14a.

In the case in which a light transmissive member 14 includes a wavelength conversion layer 14a and a light diffusing layer 14b, the light diffusing layer 14b may contain a wavelength conversion material in leu of or in addition to a light diffusing material. In other words, both the wavelength conversion layer 14a and the light diffusing layer 14b may contain a wavelength conversion material. Preferably, the light diffusing layer 14b contains a wavelength conversion material that emits light having a peak emission wavelength in a range of 450 nm to 480 nm. For such a wavelength conversion material, for example, (Sr,Ca)₂MgSi₂O₈:Eu or Ca₁₀(PO₄)₆Cl₂:Eu can be used. Having the light diffusing layer 14b positioned as the outermost layer of a light-emitting part 11 contain the wavelength conversion material described above can make the body color of the light diffusing layer 14b white when the light source 10 is not lit and viewed from above. In the case of making the body color of the light-shielding member 13 described below white, this can make the color of the upper face of the light source 10 the same color (white) in its entirety when not lit. This, as a result, can improve the esthetics of the light-emitting device 1 when viewed from the outside. When using the light-emitting elements 11a that emit blue light, furthermore, a low relative luminance intensity region might occur in the 465 nm to 480 nm wavelength range of the emission spectrum of the light-emitting device, for example. Having the light diffusing layer 14b contain a wavelength conversion material that emits light having a peak emission wavelength in a range of 450 nm to 480 nm can increase the relative luminance intensity of the low relative luminance intensity region in the emission spectrum of the light-emitting device 1. This can readily increase the luminous flux of the light-emitting device 1. The wavelength conversion material contained in the light diffusing layer 14b also has the effect of diffusing the light that enters the light diffusing layer 14b.

The outline of a light transmissive member 14 may coincide with the outline of a light-emitting element 11a or located outward from the outline of the light-emitting element 11a in the top view. This can reduce the light exiting the light-emitting element 11a that is extracted without going through the light transmissive member 14. The outline of the light transmissive member 14 may be located inward of the outline of the light-emitting element 11a in the top view.

Support Substrate

A support substrate 12 is a substrate on which a plurality of light-emitting parts 11 can be disposed. The support substrate 12 includes, for example, a base material containing an insulating material and wiring disposed on the surface of the base material. The support substrate 12 may further have a portion of the wiring on the inside thereof.

The support substrate 12 has an upper face (the first upper face U1). The support substrate 12 includes on the first upper face U1 a plurality of first terminal parts T1 and one or more first wire-connection parts WT1. The first terminal parts T1 and the first wire-connection parts WT1 are parts of the wiring. The first terminal parts T1 are disposed in the light-emitting part arrangement region A0, and the first wire-connection parts WT1 is disposed in a different region from the light-emitting part arrangement region A0. In this embodiment, the first wire-connection parts WT1 is disposed in a region outward from the light-emitting part arrangement region A0. Each first terminal part T1 includes multiple terminals, a pair of which are electrically connected to a light-emitting part 11. Each light-emitting part 11 is disposed on a pair of terminals of a first terminal part T1, electrically connecting the electrodes E of the light-emitting part 11 and the terminals of the first terminal part T1. The electrodes E of each light-emitting part 11 and the terminals of a first terminal part T1 are electrically connected via a conductive material such as a silver paste, for example. The terminals of a first terminal part T1 are, for example, a positive terminal and a negative terminal.

The first wire-connection parts WT1 is a wiring part to which one end of the first wire W1 described below is connected. The first wire-connection parts WT1 is electrically connected to the second wire-connection parts WT2 of the control unit 20 described below by using a first wire W1. This can supply the current output by the control unit 20 to the support substrate 12, lighting the light-emitting elements 11a in the light-emitting parts 11 individually or per group.

The first wire-connection parts WT1 may be arranged in columns to oppose one another with multiple first terminal parts T1 interposed between the first wire-connection parts WT1 in the top view. In FIG. 1B, four first wire-connection parts WT1 are arranged per column. In FIG. 1B, for clarity purposes, the control unit 20, the first cover members R1, and the like are omitted to make the first wire-connection parts WT1 and a portion of the support substrate 12 visible. The layout and the number of first wire-connection parts WT1 are not limited to those described above as far as a current can be appropriately supplied to each light-emitting part 11.

For the support substrate 12, an insulating material is preferably used as the base material. For the support substrate 12, a material that hardly transmits the light from the light-emitting parts 11 and the external light as well as having adequate mechanical strength is preferably used. Specifically, the support substrate 12 can be constructed with a base material made of a ceramic material, such as aluminum oxide, aluminum nitride, mullite, silicon nitride, or the like, or a resin material, such as a phenol resin, epoxy resin, polyimide resin, BT resin (bismaleimide triazine resin), polyphthalamide, or the like.

For the wiring that includes the first terminal parts T1 and the first wire-connection parts WT1, for example, a material composed of at least one among copper, iron, nickel, tungsten, chromium, aluminum, silver, gold, titanium, palladium, or rhodium, or an alloy of these can be used.

Light-Shielding Member

The light-shielding member 13 has light reflectivity to reflect the light emitted by the light-emitting parts 11 or a light absorbing property to absorb the light emitted by the light-emitting parts 11. The light-shielding member 13 covers the lateral faces of the light-emitting parts 11 so as to expose the upper faces of the light-emitting parts 11. Moreover, the light-shielding member 13 is disposed between adjacent light-emitting parts 11. Disposing a light-shielding member 13 between the light-emitting parts 11 can prevent the light from one light-emitting part 11 from overlapping the light from an adjacent light-emitting part 11. This can reduce the penetration of the light from a lit light-emitting part into an adjacent light-emitting part that is not lit, for example. This, as a result, can improve the contrast of the irradiation region of the light source 10.

In the light-emitting device 1 according to this embodiment, the light-shielding member 13 covers the lateral faces of the light-emitting elements 11a, the lateral faces of the wavelength conversion layer 14a, and the lateral faces of the light diffusing layer 14b. In the emission face of each light-emitting part 11, the upper face of the light diffusing layer 14b is exposed from the light-shielding member 13. The emission faces are the primary light extraction faces. The light-shielding member 13 covers the lateral faces and the lower face of the semiconductor structure G of each light-emitting element 11a. The light-shielding member 13 covers the lateral faces of the electrodes E of the light-emitting element 11a. The lower faces of the electrodes E are exposed from the light-shielding member 13.

In the top view, the distance between the emission faces of adjacent light-emitting parts 11 (the width of the light-shielding member 13) is, for example, 0.01 to 0.16 times, preferably 0.02 to 0.08 times the maximum length of the emission face of a light-emitting part 11. The distance between the emission faces of adjacent light-emitting parts 11 is, for example, 10 μm to 200 μm, preferably 20 μm to 100 μm. This can achieve a light-emitting device 1 having a high contrast irradiation region, while reducing the size thereof in the top view.

The light-shielding member 13 exposes the first wire-connection parts WT1 located outward from the light-emitting part arrangement region A0. Not covering the first wire-connection parts WT1 with the light-shielding member 13 can make it easy to connect the first wires W1 to the first wire-connection parts WT1. In the light-emitting device 1 according to this embodiment, as shown in FIG. 1C, the light-shielding member 13 is isolated from the first wire-connection parts WT1.

For the light-shielding member 13, for example, a resin material containing a light reflecting substance, such as white pigments or the like, can be used. Examples of light reflecting substances include titanium oxide, zinc oxide, magnesium oxide, magnesium carbonate, magnesium hydroxide, calcium carbonate, calcium hydroxide, calcium silicate, magnesium silicate, barium titanate, barium sulfate, aluminum hydroxide, aluminum oxide, zirconium oxide, silicon oxide, and the like. One of these alone or two or more of these in combination is preferably used. In the case in which the light-shielding member 13 has a light absorbing property, the light-shielding member 13 can contain a light absorbing material, such as carbon black or the like. For the base material for the light-shielding member, a resin material having as a main component a thermosetting resin, such as an epoxy resin, silicone resin, silicone modified resin, or phenol resin, or a thermoplastic resin, such as polyphthalamide, polybutylene terephthalate, or unsaturated polyester is preferably employed. Particularly, the base material preferably contains phenyl silicone. Containing phenyl silicone can make the Young's modulus of the light-shielding member once hardened higher than the Young's modulus of the resin member described below.

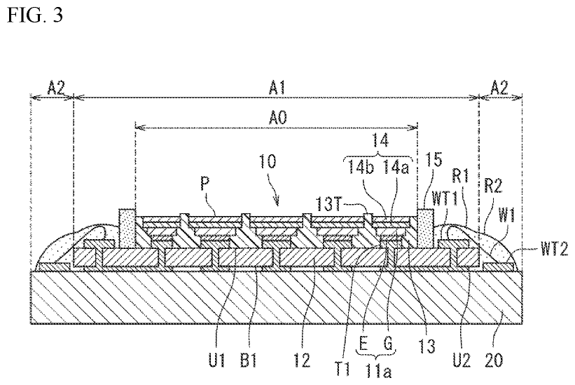

As a variation of the light-shielding member 13, as shown in FIG. 3, the height of the light-shielding member 13 located between adjacent light-emitting parts 11 may be made greater than the height of the emission faces P of the light-emitting parts 11. In other words, the light-shielding member 13 may have protruded portions 13T between the light-emitting parts 11 that are higher than the upper faces of the light-emitting parts 11. The distance between the highest position of a protruded portion 13T and the upper face of a light-emitting part 11 is, for example, 1 μm to 100 μm, preferably 15 μm to 80 μm, more preferably 30 μm to 60 μm. This can more effectively prevent the light exiting one light-emitting part 11 from overlapping the light exiting an adjacent light-emitting part 11.

Resin Member

A resin member 15 is disposed on the upper face U1 of the support substrate 12 between the light-emitting part arrangement region A0 and the first wire-connection parts WT1. Disposing a resin member 15 between the light-emitting part arrangement region A0 and the first wire-connection parts WT1 can reduce the likelihood of allowing the light-shielding member 13 to cover the first wire-connection parts WT1 located outward from the light-emitting part arrangement region A0 during the manufacturing of the light-emitting device 1 of the present disclosure. This allows a first wire W1 to be properly connected to a first wire-connection part WT1.

The resin members 15 may be disposed in the direction of columnar arrangement of the first terminal parts T1 shown as an example in FIGS. 1A and 1B. In this embodiment, the length of each resin member 15 matches the length of the light-shielding member 13 in the columnar arrangement direction of the first terminal parts T1. Furthermore, in the top view, both ends of the resin members 15 coincide with the end faces of the support substrate 12. Setting the length of the resin member 15 in this manner can more effectively reduce the likelihood of allowing the light-shielding member 13 to cover the first wire-connection parts WT1 during the manufacturing of the light-emitting device 1 of the present disclosure.

As another example of the layout of a resin member 15, as shown in FIG. 2, the resin member 15 may be disposed to surround the light-emitting parts 11 in the top view.

The height of the resin member 15 is preferably higher than the emission faces P of the light-emitting parts 11. The resin member 15 is, for example, 10 μm to 150 μm higher, preferably 20 μm to 60 μm higher than the emission faces P of the light-emitting parts 11. Setting the height of the resin member 15 higher than the emission faces P of the light-emitting parts 11 can reduce the likelihood of allowing the first cover material R11 to reach the emission faces P of the light-emitting parts 11 when disposing the first cover members R1. This can reduce the impact of the first cover members R1 on the distribution of the light from the light-emitting parts 11.

The resin material constituting the base material for the resin member 15 preferably has a lower Young's modulus than that of the resin material constituting the base material for the light-shielding member 13. Setting the Young's modulus of the resin material constituting the base material for the resin member 15 to be lower than the Young's modulus of the resin material constituting the base material for the light-shielding member 13 makes it easier to make the resin member 15 higher than the height of the light-shielding member 13 in the removal step described below. The resin material constituting the base material for the resin member 15 preferably contains, for example, dimethyl silicone, and the resin material constituting the base material for the light-shielding member 13 preferably contains phenyl silicone. This makes it easier to make the Young's modulus of the resin member 15 lower than the Young's modulus of the light-shielding member 13, thereby readily making the resin member 15 higher than the height of the light-shielding member 13.

Control Unit

A control unit 20 is positioned under the light source 10, i.e., the light source 10 is disposed on the upper face (the second upper face U2) of the control unit. The control unit 20 controls the light-emitting parts 11 individually or per group, and is for example, an IC. Disposing the light source 10 to overlap the control unit 20 in the height direction does not require separate regions for disposing the light source 10 and the control unit 20 on the same mounting surface of the mounting substrate that would be required otherwise. This can reduce the size of the light-emitting device 1 in the top view.

The control unit 20 has in the second upper face U2 a first region A1 and a second region A2 other than the first region A1. The first region A1 is the area in which the light source 10 can be disposed. In this embodiment, the first region A1 corresponds to the central region of the control unit 20 that encloses the light-emitting part arrangement region A0. The second region A2 is an area located outward from the first region A1 and has a plurality of second wire-connection parts WT2.

In the light-emitting device 1 according to this embodiment, the second wire-connection parts WT2 are arranged in two columns of second regions A2 with the light-emitting parts 11 interposed between the second wire-connection parts WT2. The arrangement direction of the second wire-connection parts WT2 is consistent with the arrangement direction of the first wire-connection parts WT1. In FIG. 1B, four second wire-connection parts WT1 are arranged per column. The layout and the number of second wire-connection parts WT2 are not limited to those described above as long as an electric current can be properly supplied to each light-emitting part 11.

The first wire-connection parts WT1 disposed on the support substrate 12 and the second wire-connection parts WT2 disposed on the control unit 20 are electrically connected via first wires W1. This allows the current output by the control unit 20 to be supplied to the support substrate 12 to individually light the light-emitting elements 11a in the light-emitting parts 11.

For the second wire-connection parts WT2, the same material as that for the first wire-connection parts WT1 can be used.

First Wire

A first wire W1 is a member that supplies the current output by the control unit 20 to the support substrate 12. The first wire W1 electrically connects a first wire-connection part WT1 disposed on the support substrate 12 and a second wire-connection part WT2 disposed on the control unit 20. For the first wire W1, for example, a metal, such as gold, copper, silver, platinum, aluminum, palladium, or the like, or an alloy containing one or more of these can be used.

First Cover Member

A first cover member R1 covers the first wire-connection parts WT1. The first cover member R1 is an insulating resin material, and has light reflectivity, for example. The first cover member R1 may be made of a material that is the same as or different from that for the light-shielding member 13.

In the light-emitting device 1 according to this embodiment, the first cover members R1 cover the first wires W1. By covering the first wires W1, the first cover members R1 play the role of protecting the first wires W1 from an external force applied to the light-emitting device 1, for example, thereby effectively reducing the deformation or the like of the first wires W1. When the first cover members R1 have light reflectivity, moreover, a portion of the returning light of the light source 10 advancing towards the first wires W1 can be reflected by the first cover members R1 to be extracted upwards easily. Moreover, this can improve the esthetics of the light-emitting device 1 because the first wires W1 covered by the first cover members R1 are less visually recognizable.

The first cover members R1 may abut the resin members 15 between the upper edges and the lower edges of the resin members 15. Positioning the upper edge of a first cover member R1 between the upper edge and the lower edge of a resin member 15 can reduce the likelihood of allowing the first cover member R1 to cover the emission faces of the light-emitting parts 11. This can reduce the impact of the first cover member R1 on the distribution of the light from the light-emitting parts 11.

Second Cover Member

The light-emitting device 1 may further include a second cover member R2. The second cover member R2 covers the second wire-connection parts WT2. The second cover member R2 is an insulating member similar to the first cover member R1, and has light reflectivity, for example. The second cover member R2 may be made of a material that is the same as or different from that for the first cover member R1. In the light-emitting device 1 of this embodiment, the second cover members R2 cover the first wires W1 and the second wires W2 described below. By covering the first wires W1 and the like, the second cover members R2 play the role of protecting the first wires W1 and the like from an external force applied to the light-emitting device 1, for example, effectively reducing the deformation or the like of the first wires W1 and the like. When the second cover members R2 have light reflectivity, moreover, a portion of the returning light of the light source 10 advancing towards the first wires W1 can be reflected by the second cover members R2 to be extracted upwards easily. Moreover, this can improve the esthetics of the light-emitting device 1 because the first wires W1 and the second wires W2 covered by the second cover members R2 are less visually recognizable. The second wire-connection parts WT2 may be covered by the first cover members R1 without providing any second cover member R2.

The first cover members R1 and the second cover members R2 may have curved upper faces as shown in FIG. 1C and FIG. 3. In the height direction, the highest position of a second cover member R2 may be lower than the highest position of a first cover member R1. The upper faces of the first cover members R1 and the second cover members R2 may each be a flat face including no curved portion, or have a shape that combines a flat face and a curved face.

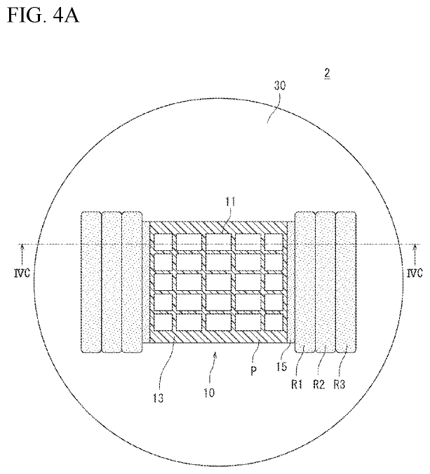

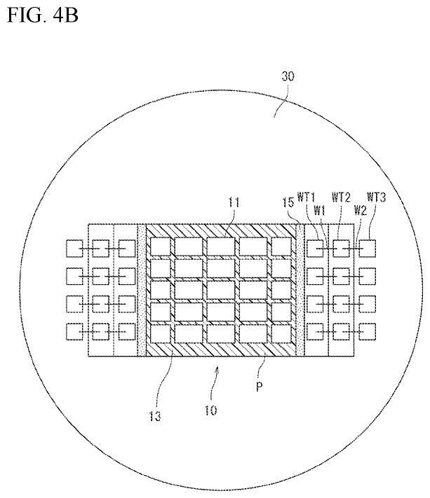

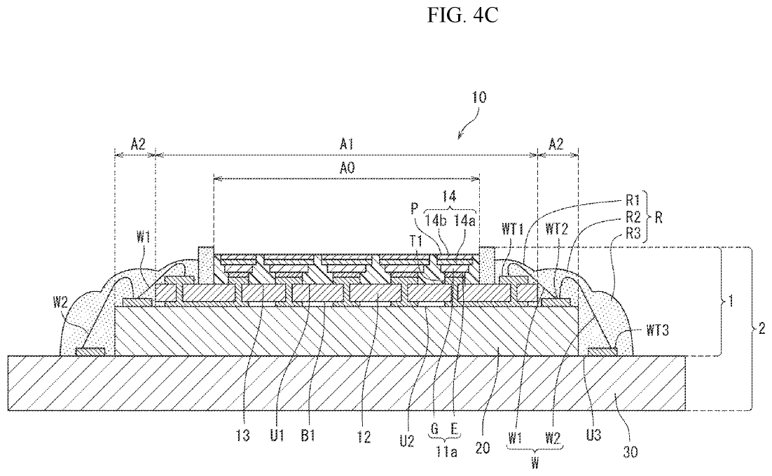

A light-emitting module 2 according to an embodiment of the present disclosure will be explained next with reference to FIG. 4A to FIG. 4C. The light-emitting module 2 according to the embodiment of the present disclosure has a light-emitting device 1, a mounting substrate 30 for placing the light-emitting device 1 on the upper face thereof, and second wires W2 for electrically connecting the light-emitting device 1 and the mounting substrate 30. The light-emitting module 2 may further include a second cover member R2, a third cover member R3, and a lens 60. Each constituent of the light-emitting module 2 will be explained in detail below. The light-emitting device 1 is as described above, and thus the explanation thereof will be omitted.

Mounting Substrate

The mounting substrate 30 is located under the control unit 20. For the mounting substrate 30, a material that hardly transmits the light emitted by the light source 10 and external light is preferably used. The mounting substrate 30 can be composed of a base material made of a ceramic, such as aluminum oxide, aluminum nitride, mullite, or the like, or a resin, such as phenol, epoxy, polyimide, BT resin, polyphthalamide, or the like.

The mounting substrate 30 has in its third upper face U3 a region where a light-emitting device 1 is disposed, and regions located outward from the region where the light-emitting device 1 is disposed. The regions located outward from the region where the light-emitting device 1 is disposed include one or more wire-connection parts WT3.

The third wire-connection parts WT3, as shown in FIG. 4B, may be arranged in columns with the light-emitting device 1 interposed between the third wire-connection parts WT3 in the top view. The arrangement direction of the third wire-connection parts WT3 is consistent with the arrangement directions of the first wire-connection parts WT1 and the second wire-connection parts WT2.

The one or more third wire-connection parts WT3 are electrically connected to the second wire-connection parts WT2 disposed on the control unit 20 via second wires W2. This allows the second wires W2 to supply the electrical current from the mounting substrate 30 to the control unit 20. For the third wire-connection parts WT3, the same material as that for the first wire-connection parts WT1 can be used. A first wire W1 and a second wire W2 may make up a single continuous wire.

Third Cover Member

A third cover member R3 covers a third wire-connection part WT3. The third cover member R3, similar to the first cover member R1 and the second cover member R2, is made of an insulating material to prevent the shorting of a third wire-connection part WT3. The third cover member R3 has light reflectivity, for example. The third cover member R3 may be made of a material that is the same as or different from that for the first cover member R1 or the second cover member R2. In the light-emitting module 2 of this embodiment, a third cover member R3 covers a portion of a second wire W2. A second wire W2 is covered by a portion of a second cover member R2 and a portion of a third cover member R3.

The first cover members R1, the second cover members R2, and the third cover members R3 may have curved upper faces as shown in FIG. 4C. In the height direction, moreover, the highest position of a third cover member R3 may be lower than the highest position of a second cove member R2, and the highest position of a second cover member R2 may be lower than the highest position of a first cover member R1.

Light-Emitting Module for Use in Flashlight that Incorporates Light-Emitting Module

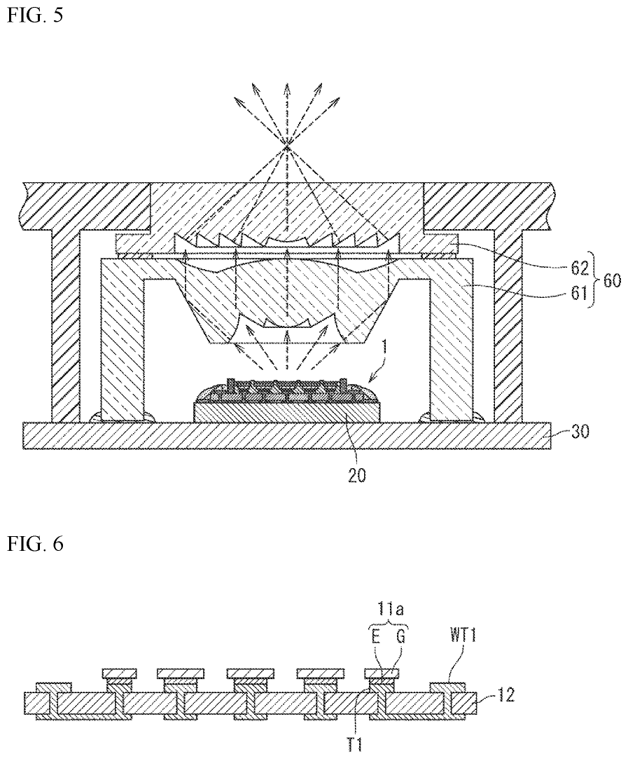

A light-emitting module according to this embodiment to be incorporated in a flashlight will be explained next with reference to FIG. 5. The light-emitting module for a flashlight according to this embodiment has a lens 60 disposed above the light source 10. As an example, a first lens 61 may be disposed above the light source 10 and a second lens 62 above that. The second lens 62 is, for example, a Fresnel lens. The Fresnel lens is disposed while opposing the lower face that has protrusions and indentations to the light source 10 through which the outgoing light from the light source 10 enters before exiting the flat upper face. Employing a Fresnel lens can reduce the thickness of the lens 60. In the light-emitting module 2 of this embodiment, the light source 10 and the control unit 20 are stacked in the height direction. This tends to increase the thickness of the light-emitting module as compared to a light-emitting module in which the light source 10 and the control unit 20 are arranged so as not to overlap. Accordingly, employing a Fresnel lens as the lens 60 or a part of the lens 60 can reduce the overall thickness of the light-emitting module. This can miniaturize the light-emitting module 2.

Method of Manufacturing Light-Emitting Device

A method of manufacturing a light-emitting device according to one embodiment of the present disclosure will be explained next. The method of manufacturing a light-emitting device according to the embodiment of the present disclosure includes a step of preparing a light source, a step of preparing a control unit, a step of disposing the light source on the control unit, and a step of electrically connecting the light source and the control unit using a first wire. Each step will be explained with reference to FIG. 6 to FIG. 15.

Step of Preparing Light Source

A step of preparing a light source includes a step of preparing a structure S by arranging a plurality of light-emitting parts 11 on the first upper face U1 of a support substrate 12, a step of disposing a resin member 15 on the first upper face U1 of the support substrate 12 between the light-emitting part arrangement region A0 and the first wire-connection parts WT1, and a step of disposing a light-shielding member 13 covering the light-emitting parts 11 on the first upper face of the support substrate 12.

—Step of Preparing Structure—

As shown in FIG. 6, the light-emitting elements 11a of light-emitting parts 11 are prepared first. The light-emitting elements 11a each have a semiconductor structure G and electrodes E. Then each light-emitting element 11a is disposed on a first terminal part T1 of the support substrate 12. The electrodes E of each light-emitting element 11a and the terminals of the first terminal part T1 are electrically connected via a conductive material, for example, a silver paste. In the method of manufacturing a light-emitting device according to this embodiment, an example of disposing light-emitting elements 11a on a single support substrate 12 is illustrated in order to simplify the explanation. A large-sized substrate that would be subsequently divided into multiple support substrates 12 may be prepared, and light-emitting elements 11a may be disposed on each of the support substrates 12 of the large-sized substrate.

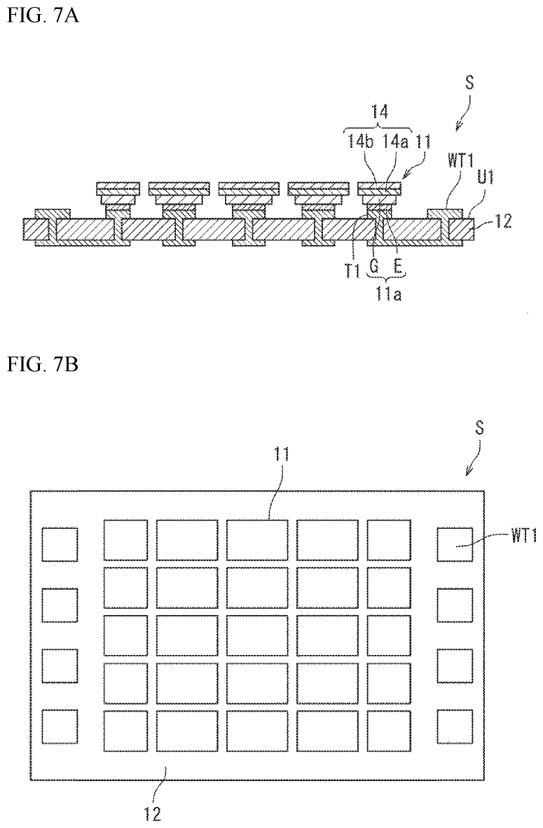

Then, as shown in FIG. 7A and FIG. 7B, a light transmissive member 14 is disposed on each light-emitting element 11a. A light transmissive member 14 may include a wavelength conversion layer 14a and a light diffusing layer 14b as described earlier. The step of disposing a light transmissive member 14 on a light-emitting element 11a includes a step of applying an uncured bonding material on the upper face of a light-emitting element 11a, a step of placing a light transmissive member 14 on the light-emitting element 11a via the uncured bonding material, and a step of bonding the light-emitting element 11a and the light transmissive member 14 by hardening or solidifying the uncured bonding material. As an example, in a die bonding apparatus (die bonder), an uncured bonding material placed in a reservoir is transferred onto the upper face of each light-emitting element 11a by using a transfer pin. Then in the same die bonder, a light transmissive sheet that will become light transmissive members 14 when divided into individual pieces is disposed across the light-emitting elements 11a. The light transmissive sheet is placed on the light-emitting elements 11a via the uncured bonding material. Next, the light transmissive sheet is divided into pieces such that a light transmissive member 14 is disposed on each light-emitting element 11a. The light transmissive sheet can be divided into pieces by cutting the light transmissive sheet between the light-emitting elements 11a using a dicing blade, for example. This is followed by heating the uncured bonding material. The uncured bonding material is, for example, a resin material having light transmissivity. In the manufacturing method according to this embodiment, the light diffusing layer 14b contains a light diffusing material such as titanium oxide, and the wavelength conversion layer 14a contains a wavelength conversion material such as a YAG phosphor. The light-emitting parts 11 each including a light-emitting element 11a and a light transmissive member 14 are arranged in rows and columns on the support substrate 12 in the top view as shown in FIG. 7B. The first wire-connection parts WT1 are arranged in columns with the light-emitting parts 11 interposed between the first wire-connection parts WT1 in the top view. In the manner described above, a structure S with a plurality of light-emitting parts 11 arranged on the first upper face U1 of a support substrate 12 is prepared.

—Step of Disposing Resin Member—

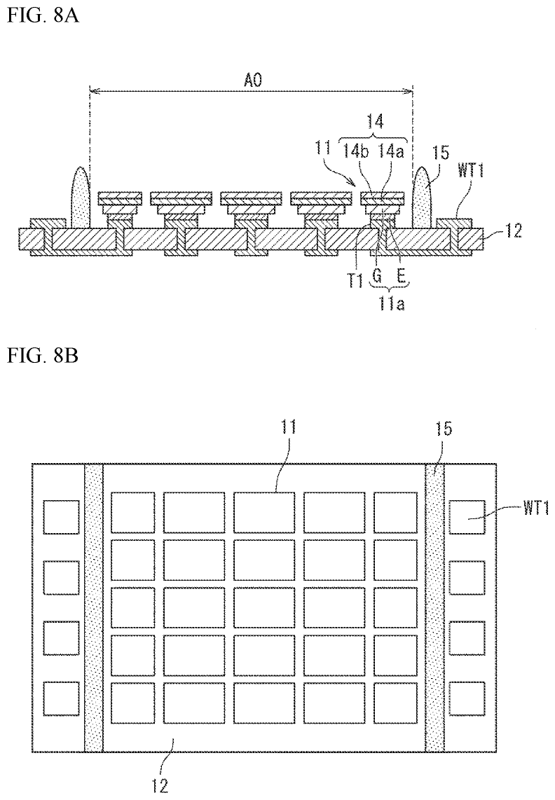

Next, as shown in FIG. 8A and FIG. 8B, resin members 15 are disposed between the light-emitting part arrangement region A0 and the first wire-connection parts WT1 in the top view. The resin members 15 are disposed by applying an uncured resin material that will become the resin members 15 by using a dispensing device. The uncured resin material may be applied in a single shot or multiple shots. The viscosity of the uncured resin material for forming the resin members 15 is, for example, 300 Pa·s to 500 Pa·s. Subsequently, the uncured resin material can be heated, for example, to form the resin members 15. The width of each resin member 15 in the direction from the first wire-connection parts WT1 to the light-emitting parts 11 is, for example, 10 μm to 300 μm, preferably 50 μm to 150 μm. The height of the resin members 15 is, for example, 10 μm to 300 μm, preferably 100 μm to 250 μm. In the present specification, the same term, resin members, is used to refer to the resin members 15 both before and after the partial removal step.

The resin members 15, as shown in FIG. 8B, may be arranged along the columnar arrangement direction of the first terminal parts T1. With respect to the layout, as explained earlier with reference to FIG. 2, a resin member 15 may be disposed to surround the light-emitting parts 11 in the top view. When formed in this manner, the uncured material that will form the light-shielding member 13 can be dammed by the resin member 15 in the columnar arrangement direction of the first terminal parts T1 as well, during the manufacturing of a light-emitting device 1 of the present disclosure.

Disposing the resin members 15 between the light-emitting part arrangement region A0 and the first wire-connection parts WT1 can reduce the likelihood of allowing the light-shielding member 13 to cover the first wire-connection parts WT1 during the step of disposing a light-shielding member 13 described below. Considering the fact that the resin members 15 will be partially removed later in the removal step, the resin members 15 are preferably formed higher than the height of the resin members 15 in the light source 10 that would result after the manufacturing process. The resin members 15 are provided to be larger in height than the light-emitting parts 11. For the purpose of making the heights of the resin members 15 higher than the emission faces of the light-emitting parts 11 in the removal step, a resin material having a low Young's modulus is preferably used as the base material for the resin members 15. The resin material constituting the base material for the resin member 15 is, for example, dimethyl silicone. This makes it easier to achieve a larger height for the resin members 15 than the emission faces of the light-emitting parts 11 in the removal step.

—Step of Disposing Light-Shielding Member—

The step of disposing a light-shielding member may include a step of disposing a light-shielding member 13 to be higher than the emission faces of the light-emitting parts 11, and a step of partially removing the light-shielding member 13 and the resin members 15 from the upper side of the light source 10 to expose the emission faces of the light-emitting parts 11. In the present specification, the same term, light-shielding member, is used to refer to the light-shielding member 13 both before and after the partial removal step.

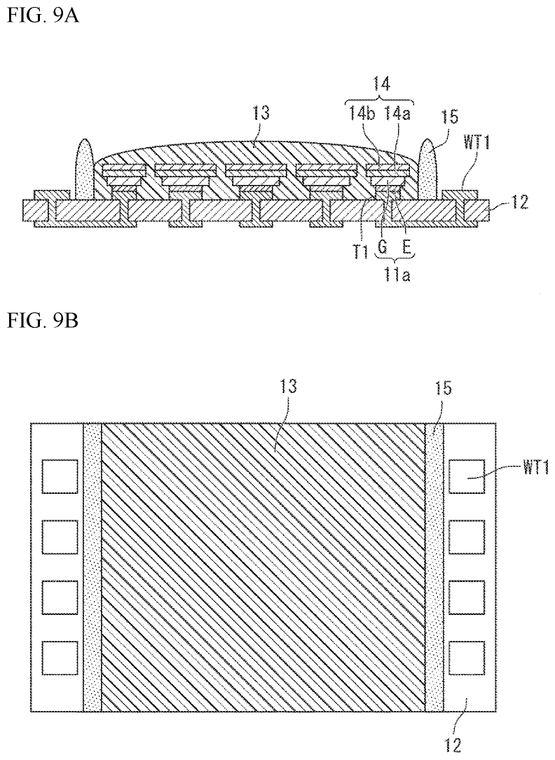

First, as shown in FIG. 9A, an uncured resin material that will become the light-shielding member 13 is disposed in the region interposing or surrounded by the resin members 15. The uncured resin material penetrates between and encapsulate the light-emitting parts 11. The uncured resin material that will become the light-shielding member 13 can be disposed by using a discharge device such as a dispenser. The uncured resin material may be applied in a single shot or multiple shots. The viscosity of the uncured resin material for forming the light-shielding member 13 is, for example, 100 Pa·s to 250 Pa·s. The uncured resin material comes into contact with the resin members 15 between the upper and lower edges of the resin members 15. Disposing the uncured resin material in this manner can reduce the likelihood of allowing the uncured resin material to run over the resin members 15 to flow onto the first wire-connection parts WT1. This can reduce the likelihood of allowing the uncured resin material that will become he light-shielding member 13 to cover the first wire-connection parts WT1.

By subsequently conducting a heating process, the resin material for forming the light-shielding member 13 is hardened or solidified. This can form the light-shielding member 13 that covers the light-emitting parts 11 as shown in FIG. 9A and FIG. 9B. In this embodiment, the light-shielding member 13 is provided to be larger in height than the emission faces P of the light-emitting parts 11.

The Young's modulus of the resin material constituting the base material for the light-shielding member 13 is preferably higher than the Young's modulus of the resin material constituting the base material for the resin members 15. In other words, the rigidity of the light-shielding member 13 is preferably higher than the rigidity of the resin members 15. For example, the resin material constituting the base material for the resin member 15 contains dimethyl silicone, and the resin material constituting the base material for the light-shielding member 13 contains phenyl silicone.

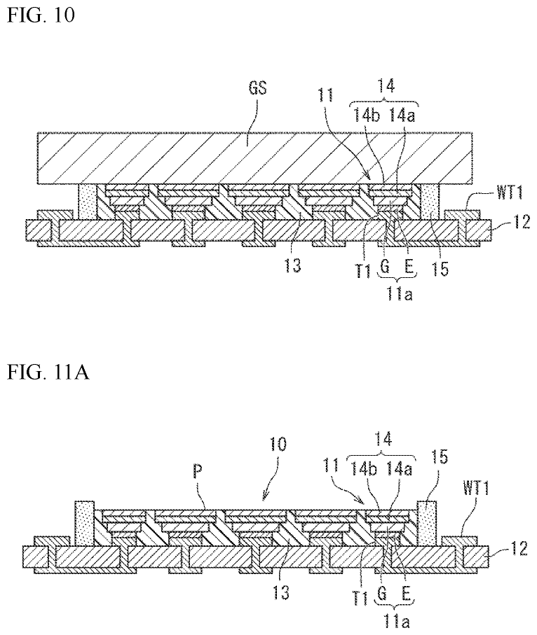

Then as shown in FIG. 10, a step of partially removing the light-shielding member 13 and the resin materials 15 is conducted. The removal step, as an example, removes a portion of the light-shielding member 13 and a portion of each resin member 15 by using a grinding and polishing apparatus. Specifically, the members are ground and polished by pushing the grinding stone GS of the grinding and polishing apparatus against the light-shielding member 13 and the resin members 15.

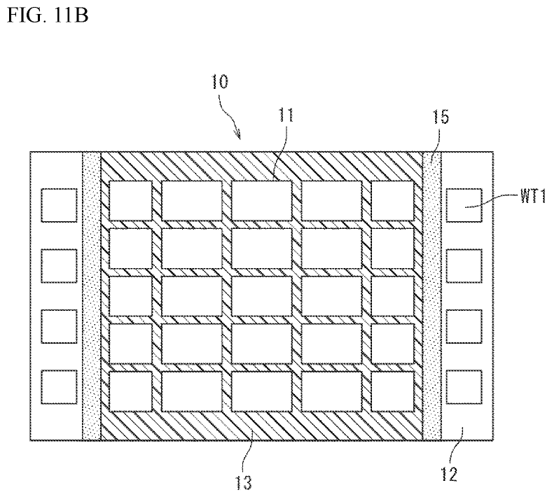

To describe in detail, the removal step is conducted by pressing the grinding stone GS against the light-shielding member 13 and the resin member 15 as shown in FIG. 10. The pressing is done by applying a pressing force, for example, of 0.2 N·m to 2 N·m, preferably 0.4 N·m to 0.7 N·m. Here, setting the Young's modulus of the resin members 15 lower than the Young's modulus of the light-shielding member 13 allows the grinding and polishing to be conducted while deforming the resin members 15 more than the light-shielding member 13. When the pressure from the grinding stone GS is released after the completion of the grinding and polishing, the resin members 15 expand to regain their original shapes. This allows the resin members 15 to be larger in height than the emission faces of the light-emitting parts 11 as shown in FIG. 11A. The same applies to the light-shielding member 13 and the light transmissive member 14. Specifically, setting the Young's modulus of the light transmissive member 14 lower than the Young's modulus of the light-shielding member 13 allows the light-shielding member 13 to expand to regain its original shape as the pressure from the grinding stone GS is released when the grinding and polishing is done. This can make the light-shielding member 13 larger in height than the emission faces of the light-emitting parts 11 as shown in FIG. 3.

If a large sized substrate that includes multiple support substrates 12 is used in the step of preparing a light source, the substrate is divided into individual support substrates 12. For the dividing method, for example, dicing, Thomson punching, supersonic processing, laser processing, or the like, can be used.

In the manner described above, a light source 10 of the present disclosure can be prepared. A light source can be prepared by following the manufacturing steps described above in part or whole, or through a transfer, including a purchase.

Step of Preparing Control Unit

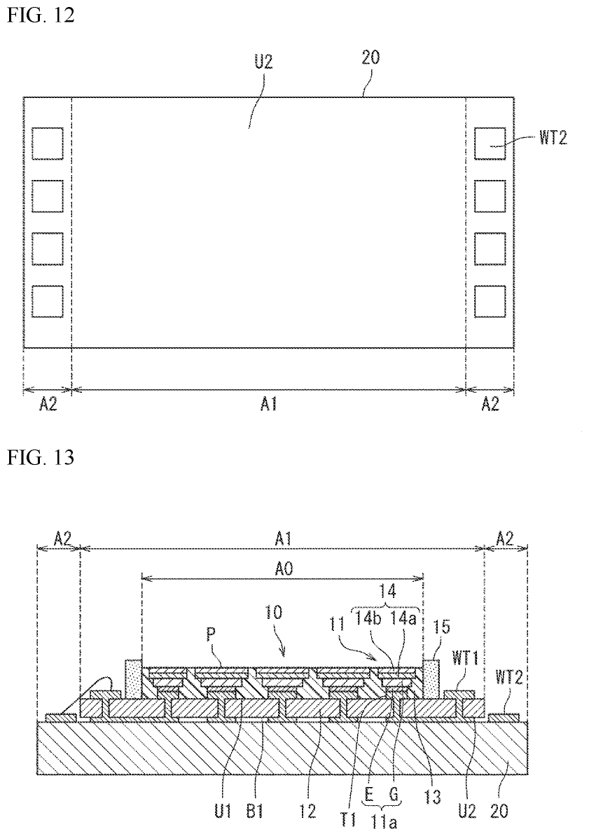

Next, a control unit 20 is prepared. The step of preparing a control unit may be conducted before, after, or simultaneously with the step of preparing a light source. The control unit 20, as shown in FIG. 12, includes a second upper face U2, and in the second upper face U2 a first region A1 where a light source 10 can be disposed and one or more second wire-connection parts WT2 disposed in second regions A2 other than the first region A1. The second wire-connection parts WT2 are arranged in columns on the second regions A2 with the first region A1 interposed between the second wire-connection parts WT2. In the manufacturing method of this embodiment, there is no wiring formed in the first region A1. A control unit may be prepared by following the manufacturing steps described above, or through a transfer, including a purchase.

Step of Disposing Light Source

Next, as shown in FIG. 13, a light source 10 is disposed on the control unit 20. The light source 10 is disposed on the first region A1 located in the second upper face U2 of the control unit 20. The light source 10 is bonded to the first region A1 of the control unit 20, for example, via a bonding material such as a silver paste. In this state, the light source 10 and the control unit 20 are not electrically connected yet.

First Wire-Connection Step

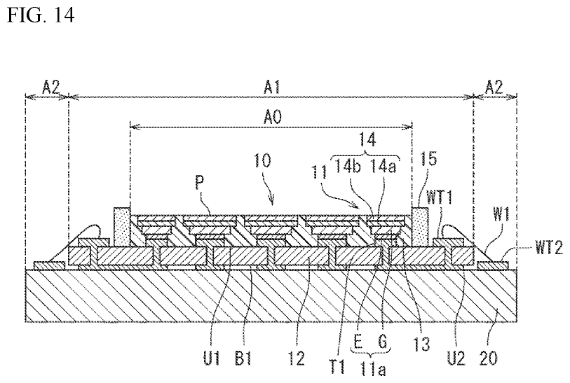

Next, the light source 10 and the control unit 20 are electrically connected using a first wire W1. Specifically, as shown in FIG. 14, the first wire-connection parts WT1 on the support substrate 12 and the second wire-connection parts WT2 on the control unit 20 are connected by the first wires W1. As an example, the first wires W1 at one end are connected to the first wire-connection parts WT1, and then the first wires at the other end are connected to the second wire-connection parts WT2. The first wires W1 at one end may be connected to the second wire-connection parts WT2, and then the first wires at the other end to the first wire-connection parts WT1. This allows the current from the control unit 20 to be supplied to the light source 10 via the first wires W1. In the first wire-connection step, the first wires W1 at one end may be connected to the first wire-connection parts WT1, followed by connecting the first wires W1 at the other end to the second wire-connection parts WT2. The first wire-connection step may be conducted after the step of disposing a light-emitting device 1 on a mounting substrate described below.

Step of Disposing First Cover Member

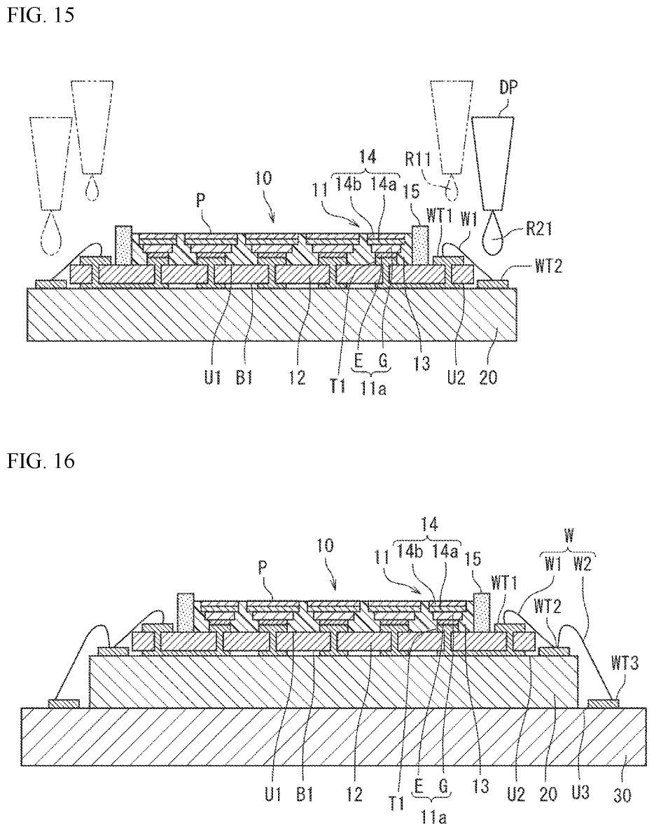

The manufacturing method of this embodiment may further include a step of disposing a first cover member. In the step of disposing a first cover member, a first cover member R1 is disposed to cover the first wire-connection parts WT1. The step of disposing a first cover member, as shown in FIG. 15, includes a step of dispensing an uncured first cover material R11 that will become the first cover members R1 from above the first wire-connection parts WT1. Here, the first cover material R11 is dammed by the resin members 15. This can reduce the likelihood of allowing the first cover material R11 to creep up onto the upper face of the light-shielding member 13. This can reduce the unintended impact of the hardened or solidified first cover members R1 on the distribution of the light from the light source 10. A desired light-emitting device can be easily manufactured even if the first wires W1 are covered by the first cover material 11 because the resin members 15 are provided. The uncured first cover material R11 used to form the first cover members R1 is discharged, for example, from the nozzle DP of a resin discharge device (e.g., dispenser).

The first cover members R1 preferably cover all of the first wire-connection parts WT1 arranged in columns. In other words, the nozzle DP of the dispensing equipment preferably dispenses the first cover material R11 continuously while being moved along the arrangement direction of the first wire-connection parts WT1. This allows the first cover material R11 to cover all the first wire-connection parts WT1 arranged in columns in a lump. The first cover material R11 may be disposed on the first wire-connection parts WT1 using a fixed nozzle DP while moving the work, the light-emitting device, placed in the dispensing equipment. This also applies to the second cover material R21 and the third cover material R31 described below.

Step of Disposing Second Cover Member

The manufacturing method of this embodiment may further include a step of disposing a second cover member. In the step of disposing a second cover member, a second cover member R2 is disposed to cover the second wire-connection parts WT2 on the control unit 20. The step of disposing a second cover member may be conducted before or after the step of disposing a first cover member. The step of disposing a second cover member, as shown in FIG. 15, includes a step of dispensing an uncured second cover material R21 that will become a second cover member R2 from above the second wire-connection parts WT2. The second cover members R2 preferably cover, together with the first cover members R1, the first wires W1.

The second cover members R2 preferably cover all of the second wire-connection parts WT2 arranged in columns. In other words, the nozzle DP of the dispensing equipment preferably dispenses the second cover material R21 continuously while being moved along the arrangement direction of the second wire-connection parts WT2. This allows the second cover material R21 to cover all the second wire-connection parts WT2 arranged in columns in a lump.

The uncured first cover material R11 constituting the first cover members R1 and the uncured second cover material R21 constituting the second cover members R2 may be hardened or solidified at the same time in one heating step, or individually subjected to a hardening or solidification step. The two uncured resin materials are preferably hardened or solidified at the same time. This can reduce the time required for the hardening or solidification step as compared to the case of individually conducting a hardening or solidification step. The hardening or solidification step is performed, for example, at a temperature in a range of 100° C. to 150° C. range for the duration of 30 to 90 minutes.

With respect to the suitable amounts to be dispensed, the amount of the second cover material R21 may be set higher than the first cover material R11. Setting the dispensed amount of the first cover material R11 smaller than the dispensed amount of the second cover material R21 can readily reduce the likelihood of allowing the first cover material R11 to creep up onto the emission face P of the light source 10. Furthermore, reducing the resin material that covers the first wire-connection parts WT1 near the light-emitting parts 11 can readily reduce the thermal shock applied by the light-emitting parts 11 to the vicinity of the first wire-connection parts WT1. The step of disposing a first cover member R1 and the step of disposing a second cover member R2 may be conducted after the step of disposing a light-emitting device 1 on a mounting substrate described below.

A light-emitting device of the present disclosure can be manufactured by following the manufacturing steps described above.

Method of Manufacturing Light-Emitting Module

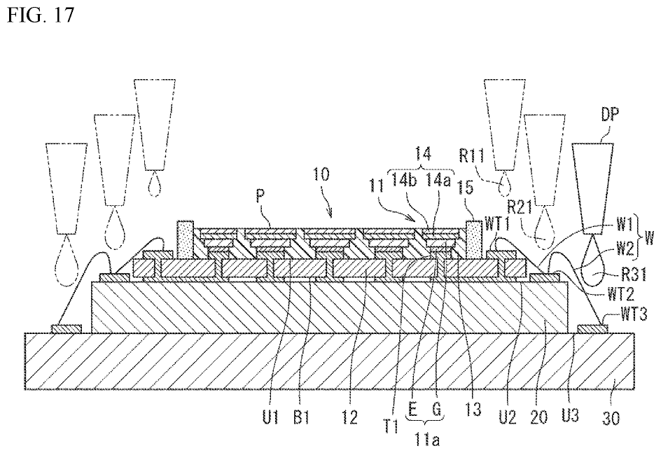

A method of manufacturing a light-emitting module according to one embodiment of the present disclosure will be explained next. The method of manufacturing a light-emitting module according to this embodiment of the present disclosure includes a step of preparing a mounting substrate, a step of disposing on the third upper face of the mounting substrate a light-emitting device obtained by the method of manufacturing a light-emitting device described above, and a step of connecting the second wire-connection parts on the control unit and the third wire-connection parts on the mounting substrate described above by using second wires. Each step will be explained with reference to FIG. 16 and FIG. 17.

Step of Preparing Mounting Substrate

A mounting substrate 30 is prepared first. The mounting substrate 30 has a third upper face U3 and one or more third wire-connection parts WT3 on the third upper face U3. The mounting substrate 30 has in the third upper face U3 a region where the light-emitting device 1 is disposed and regions located outward from the region where the light-emitting device 1 is disposed. The one or more third wire-connection parts WT3 are disposed in the regions located outward from the region where the light-emitting device 1 is disposed. The third wire-connection parts WT3 are arranged in columns with the region where the light-emitting device 1 is disposed interposed between the third wire-connection parts WT3. A light-emitting device obtained by the method of manufacturing a light-emitting device described above is disposed on the mounting substrate 30.

Step of Disposing Light-Emitting Device

A light-emitting device 1 is disposed on the mounting substrate 30. Specifically, the light-emitting device 1 is disposed on the third upper face U3 of the mounting substrate 30 via a bonding material such as a silver paste. In this state, the light-emitting device 1 and the mounting substrate 30 are not electrically connected yet.

Second Wire-Connection Step

Then the light-emitting device 1 and the mounting substrate 30 are electrically connected using second wires W2. Specifically, as shown in FIG. 16, the second wire-connection parts WT2 on the control unit 20 and the third wire-connection parts WT3 on the mounting substrate 30 are electrically connected by using the second wires W2. As an example, the second wires W2 at one end are connected to the second wire-connection parts WT2, and then the second wires at the other end are connected to the third wire-connection parts WT3. The second wires at one end may be connected to the third wire-connection parts WT3, and then the second wires at the other end to the second wire-connection parts WT2. This allows the current from the mounting substrate 30 to be supplied to the control unit 20 via the second wires W2. In the second wire-connection step, the second wires W2 at one end may be connected to the second wire-connection parts WT2, followed by connecting the other ends of the second wires W1 to the third wire-connection parts WT3. By conducting the first wire-connection step immediately before the second wire-connection step, the two wire-connection steps can be conducted continuously. In this manner, the two wire-connection steps can be conducted continuously in the same wire bonding equipment, for example. This, as a result, can reduce the time required for the wire-connection steps. A first wire W1 and a second wire W2 may make up a single continuous wire. In this case, for example, wire bonding is conducted in the order of a first wire-connection part WT1, a second wire-connection part WT2, and a third wire-connection part WT3 to connect the first wire-connection part WT1, the second wire-connection part WT2, and the third wire-connection part WT3 with a single wire. Similarly, wire bonding may be conducted in the order of a third wire-connection part WT3, a second wire-connection part WT2, and a first wire-connection part WT1 to connected the first wire-connection part WT1, the second wire-connection part WT2, and the third wire-connection part WT3 with a single wire.

Step of Disposing Third Cover Member

The manufacturing method of the present embodiment may further include a step of disposing a third cover member. In the step of disposing a third cover member, a third cover member R3 is disposed to cover the third wire-connection parts WT3. The step of disposing a third cover member, as shown in FIG. 17, includes a step of dispensing an uncured third cover material R31 that will form a third cover member R3 from above the third wire-connection parts WT3. The uncured third cover material R31, similar to the first cover material R11 and the second cover material R21, may be disposed by using a resin discharge device such as a dispenser. The third cover members R3 are preferably disposed to cover the second wires W2. The second wires W2 may be covered by both the second cover members R2 and the third cover members R3.

The step of disposing a first cover member and the step of disposing a second cover member may be conducted during the step of preparing a light-emitting device, or continuously with the step of disposing a third cover member. The step of disposing a first cover member, the step of disposing a second cover member, and the step of disposing a third cover member are preferably conducted continuously. This allows the steps of disposing three resin members to be conducted continuously in the same discharge apparatus, for example. This, as a result, can reduce the time required for the steps of disposing resin members.

With respect to the suitable amounts to be dispensed, the cover materials may be arranged in descending order: the third cover material R31, the second cover material R21, and the first cover material R11.

A light-emitting module of the present disclosure can be manufactured by following the steps described above.

The embodiments disclosed above are exemplary in every aspect, and are not intended to serve as the grounds for limited interpretation. Accordingly, the technical scope of the present disclosure should not be construed only by the embodiments descried above, but defined by the scope of the claims. Furthermore, the technical scope of the present disclosure encompasses the meanings equivalent to the scope of the claims and all modifications falling within the scope.

1. A method of manufacturing a light-emitting device, the method comprising:
preparing a light source, which comprises:
(a) preparing a structure comprising:
a support substrate having a first upper face and comprising, on the first upper face, a plurality of first terminal parts disposed in the light-emitting part arrangement region, and one or more first wire-connection parts, and
a plurality of light-emitting parts disposed in the light-emitting part arrangement region and electrically connected to the first terminal parts, each of the plurality of light-emitting parts having an emission face,
(b) disposing a resin member on the first upper face between the light-emitting part arrangement region and the one or more first wire-connection parts in a top view, and
(c) disposing a light-shielding member in contact with the resin member while the first wire-connection parts and the emission faces of the light-emitting parts are exposed from the light-shielding member in the top view;
preparing a control unit having a second upper face, the control unit comprising, on the second upper face, a first region where the light source is to be disposed, and one or more second wire-connection parts disposed in a second region other than the first region;
disposing the light source on the first region of the control unit; and
connecting the first wire-connection parts and the second wire-connection parts by a first wire.

2. The method according to claim 1, wherein:
in the step of disposing the light-shielding member, a height of the light-shielding member is greater than heights of the emission faces of the light-emitting parts; and
the step of disposing the light-shielding member comprises partially removing the light-shielding member and the resin member from the upper side of the light source to expose the emission faces of the light-emitting parts from the light-shielding member.

3. The method according to claim 2, wherein:
in the step of removing the light-shielding member and the resin member, a height of the resin member is greater than the heights of the emission faces of the light-emitting parts.

4. The method according to claim 1, wherein a Young's modulus of a resin material of the resin member is lower than a Young's modulus of a resin material of the light-shielding member.

5. The method according to claim 4, wherein:
the resin material of the resin member contains dimethyl silicone; and
the resin material of the light-shielding member contains phenyl silicone.

6. The method according to claim 2, wherein, in the step of removing the light-shielding member and the resin member, a height of the light-shielding member disposed between adjacent light-emitting parts is greater than the heights of the emission faces of the light-emitting parts.

7. The method according to claim 1, wherein:
the support substrate comprises a plurality of the first wire-connection parts arranged in columns with the light-emitting part arrangement region interposed between the first wire-connection parts in the top view, and
the resin member is disposed along a columnar arrangement direction of the first terminal parts.

8. The method according to claim 1, wherein, in the step of disposing a resin member, the resin member is disposed to surround the light-emitting part arrangement region in the top view.

9. The method according to claim 1, further comprising, subsequent to the first wire-connection step, disposing a first cover member that covers the first wire-connection parts.

10. The method according to claim 1 further comprising disposing a cover member that covers the second wire-connection parts.

11. A method of manufacturing a light-emitting module, the method comprising:
preparing a mounting substrate comprising one or more mounting substrate wire-connection parts on a mounting substrate upper face;
disposing, on the mounting substrate upper face, a light-emitting device manufactured by the method according to claim 1; and
connecting the second wire-connection parts of the control unit and the mounting substrate wire-connection parts by a second wire.

12. The method of manufacturing a light-emitting module according to claim 11, further comprising disposing a cover member that covers the mounting substrate wire-connection parts.

13. A light-emitting device comprising:
a light source comprising:
a support substrate having a first upper face and comprising, on the first upper face, a plurality of first terminal parts disposed in the light-emitting part arrangement region, and one or more first connection parts,
a plurality of light-emitting parts disposed in the light-emitting part arrangement region and electrically connected to the first terminal parts, each of the plurality of light-emitting parts having an emission face,
a resin member disposed on the first upper face between the light-emitting part arrangement region and the one or more first wire-connection parts in a top view, and
a light-shielding member disposed in contact with the resin member while the first wire-connection parts and the emission faces of the light-emitting parts are exposed from the light-shielding member in the top view;
a control unit having a second upper face, the control unit comprising, on the second upper face, a first region where the light source is disposed, and one or more second wire-connection parts disposed in a second region other than the first region;
a first wire connecting the first wire-connection parts and the second wire-connection parts; and
a first cover member covering the first wire while the emission faces of the light-emitting parts are exposed from the first cover member.

14. The light-emitting device according to claim 13 wherein a height of the resin member is greater than heights of the emission faces of the light-emitting parts.

15. The light-emitting device according to claim 14 wherein a Young's modulus of a resin material of the resin member is lower than a Young's modulus of a resin material of the light-shielding member.

16. The light-emitting device according to claim 15 wherein:
the resin material of the resin member contains dimethyl silicone; and
the resin material of the light-shielding member contains phenyl silicone.

17. The light-emitting device according to claim 13 wherein a height of the light-shielding member disposed between adjacent light-emitting parts is greater than heights of the emission faces of the light-emitting parts.

18. The light-emitting device according to claim 13, wherein:
the support substrate comprises a plurality of the first wire-connection parts arranged in columns with the light-emitting part arrangement region interposed between the first wire-connection parts in the top view; and
the resin member is disposed along a columnar arrangement direction of the first terminal parts.

19. The light-emitting device according to claim 13 wherein the resin member is disposed to surround the light-emitting parts in the top view.

20. The light-emitting device according to claim 13 wherein the first cover member is in contact with the resin member between an upper edge and a lower edge of the resin member.

21. The light-emitting device according to claim 13 further comprising a second cover member that covers the second wire-connection parts.

22. A light-emitting module comprising:
a light-emitting device according to claim 13;
a mounting substrate having a third upper face on which the light-emitting device is disposed, the mounting substrate comprising one or more third wire-connection parts disposed on a region of the third upper face other than the region where the light-emitting device is disposed; and
a second wire connecting the second wire-connection parts of the control unit and the third wire-connection parts of the mounting substrate.

23. The light-emitting module according to claim 22 further comprising a third cover member that covers the third wire-connection parts.
